(19) United States
(12) Patent Application Publication
(10) Pub. No.: US 2025/0327621 A1
(43) Pub. Date: Oct. 23, 2025

(54) FURNACE CHAMBER

(71) Applicant: Illinois Tool Works Inc., Glenview, IL (US)

(72) Inventors: De WEI, Suzhou New District (CN); Yuexin CHEN, Suzhou New District (CN)

(21) Appl. No.: 18/855,568

(22) PCT Filed: Mar. 31, 2023
(86) PCT No.: PCT/US2023/017140

§ 371 Date: Oct. 9, 2024

(30) Foreign Application Priority Data
Apr. 12, 2022 (CN) 202210379642.1

(51) Int. Cl. F27B 9/30; B23K 1/008; F27B 9/12; F27B 17/00

(52) U.S. Cl. CPC F27B 9/3005; B23K 1/008; F27B 17/0016; F27B 2009/124

(57) ABSTRACT

The present application provides a furnace chamber for a reflow furnace, the furnace chamber including a high temperature zone and a cooling zone, the cooling zone including: a base plate provided with a through hole; an airflow source provided above the base plate, which delivers airfl 5 ow to the base plate and delivers airflow through the through hole on the base plate, wherein the base plate includes a bottom surface facing away from the airflow source, at least a portion of the bottom surface being arranged at an angle to a horizontal direction of the furnace chamber, the cooling zone being provided with a processing area, and the bottom surface of the 10 base plate being inclined to at least one side of the processing area along a conveying direction of a circuit board. A flux condensed on the bottom surface flows along a ramp to a lower edge of the base plate. The base plate is located above the processing area, and the lower edge of the base plate is located in an area other than the at least one side of the processing area, as viewed from the top down. In 15 this way, the flux condensed on the bottom surface of the base plate flows along the ramp to the lower edge of the base plate, out of the lower edge and dripping to an area outside at least one side of the processing area without dripping onto the circuit board of the processing area.

### TECHNICAL FIELD

The present application relates to a furnace chamber, in particular to a furnace chamber for a reflow furnace.

### BACKGROUND

In the production of printed circuit boards, electronic elements are typically mounted to circuit boards using a process called “reflow soldering.” In a typical reflow soldering process, a soldering paste (e.g., tin paste) is deposited into a selected area on a circuit board and a wire of one or more electronic elements is inserted into the deposited soldering paste. The circuit board then passes through a reflow furnace in which the solder paste refluxes in a high temperature zone of the reflow furnace (i.e., is heated to a melting or reflux temperature) and then cools in a cooling zone of the furnace chamber to electrically and mechanically connect the wires of the electronic components to the circuit board. As used herein, the term “circuit board” or “printed circuit board” includes a substrate assembly of any type of electronic element, such as includes a wafer substrate. In the reflow furnace, air or a substantially inert gas (e.g. nitrogen) is typically used as a working gas, and different working gases are used for circuit boards with different process requirements. The working gas is filled in the reflow furnace chamber, and the circuit board is welded in the working gas as it is conveyed through the chamber via the conveyor.

### SUMMARY

Solder pastes include not only solder, but also fluxes that make the solder wet and provide good welding seams. Other additives such as solvents and catalysts may also be included. After the solder paste is deposited on the circuit board, the circuit board is conveyed via the conveyor to pass through a plurality of high temperature zones in the reflow furnace chamber. The heat in the high temperature zone melts solder paste, and organic compounds that mainly include fluxes contain volatile organics (“VOCs”) and thus are vaporized to form vapors, thereby forming “contaminants”. These contaminants mix with the working gas in the high temperature zone to form exhaust gases. Accumulation of these contaminants in the reflow furnace chamber can cause certain problems. For example, as the circuit board is conveyed from the high temperature zone to the cooling zone, contaminants also flow to the cooling zone, where they are condensed into liquid and/or solid onto the circuit board after cooling, thus contaminating the circuit board and necessitating subsequent cleaning steps. In addition, condensate may also drip onto subsequent circuit boards, which may damage the components on the circuit boards or necessitate subsequent cleaning steps of the contaminated circuit boards.

In the furnace chamber of the reflow furnace, the processing area of the high temperature zone is connected to the processing area of the cooling zone. When soldering a circuit board, the circuit board is first conveyed to the processing area of the high temperature zone for heat soldering, and then the soldered circuit board is conveyed to the processing area of the cooling zone for cooling. A cooling box is provided above the processing area of the cooling zone, a through hole is provided on the base plate of the cooling box, and the air flow source is contained in the cooling box. The air flow source is used to provide a cold air flow and blow the cold air flow down from the through hole on the base plate to the processing area of the cooling zone via a blower to cool the circuit board located in the processing area. As the exhaust gases flow from the high temperature zone to the cooling zone, the flux constituents in the exhaust gases cool in the cooling zone and condense on the bottom surface of the base plate of the cooling box above the processing area of the cooling zone, such as an area other than the through hole.

By way of observation, the inventors recognize that as the amount of flux condensed on the bottom surface of the base plate continues to accumulate, and because cold air flows down through the through hole on the base plate at a certain speed, the flux accumulated on the base plate drips down onto the circuit board in the processing area of the cooling zone, thereby damaging the circuit board. In the prior art, the base plate is set parallel to the horizontal direction of the furnace chamber, so that the flux will condense on the approximate entire bottom surface of the base plate. Due to the downward flow of air from the through hole on the base plate and the gravity of the condensed flux itself, the condensed flux drips down from approximately the entire bottom surface of the base plate onto almost all circuit boards in the processing area below the entire bottom surface. When the flux condensed to the bottom plate reaches a certain amount after a period of time, the flux drips down from the base plate onto the circuit board. At this time maintenance is required on the cooling zone, such as cleaning the base plate of the cooling zone. The structure of the above-described base plate in the prior art results in a shorter maintenance time of the cooling zone, for example approximately 2 weeks.

In order to solve at least one of the above problems, the present application provides a furnace chamber having a cooling zone capable of preventing the flux in the exhaust gases from dripping onto a circuit board in a processing area of the cooling zone, thus effectively extending the maintenance time of the cooling zone.

In order to achieve the above objectives, a first aspect of the present application provides a furnace chamber for a reflow furnace, the furnace chamber including a high temperature zone and a cooling zone, the cooling zone including: a base plate provided with a through hole; an airflow source provided above the base plate, the airflow source delivering airflow to the base plate and delivering airflow through the through hole on the base plate, wherein the base plate includes a bottom surface facing away from the airflow source, at least a portion of the bottom surface being disposed at an angle to a horizontal direction of the furnace chamber, wherein the cooling zone is provided with a processing area and the bottom surface being disposed at an angle to the horizontal direction of the furnace chamber is inclined to at least one side of the processing area.

In the present invention, the base plate is disposed at an angle to the horizontal direction of the furnace chamber and the base plate is tilted to at least one side of the processing area of the cooling zone along the conveying direction of the circuit board, thereby enabling the flux condensed on the base plate to flow along the ramp of the base plate to at least one side of the furnace chamber (located outside of the processing area) into a collection tank. The flux flowing down along the ramp of the base plate will flow outside the processing area and therefore will not flow onto the PCB board in the processing area.

According to the first aspect described above, the bottom surface disposed at an angle to the horizontal direction of the furnace chamber is inclined to both sides of the processing area.

According to the first aspect described above, the base plate includes a bent flat plate.

According to the first aspect described above, the base plate includes a flat plate.

According to the first aspect described above, the furnace chamber is used to process a PCB board. The PCB board is placed below the base plate. The high temperature zone is provided with a processing area. The processing area of the high temperature zone is connected to the processing area of the cooling zone. During the processing process, the PCB board is conveyed through the processing area of the high temperature zone and the processing area of the cooling zone in a sequential manner.

According to the first aspect described above, the base plate includes a first portion, a second portion, and an adapter, the first portion and the second portion being bent in connection at the adapter, and the first portion and the second portion extending downwardly from the adapter to both sides of the cooling zone at an angle with the horizontal direction of the furnace chamber.

According to the above first aspect, a plurality of first through holes are provided on the first portion, and a plurality of second through holes are provided on the second portion, the axial direction of the first through holes being perpendicular to a plane in which the first portion is located, and the axial direction of the second through holes being perpendicular to a plane in which the second portion is located.

According to the first aspect described above, the bending angle between the first portion and the second portion ranges from 165° to 171°.

According to the first aspect described above, the bending angle between the first portion and the second portion is 168°.

In the present invention, the airflow may flow vertically downward from the top of the furnace chamber, and when the axial direction of the through holes on the first portion of the base plate and the second portion of the base plate is set perpendicular to the plane in which the first portion of the base plate and the second portion of the base plate are located, the angle of the airflow out of the through hole will be oblique. If the bending angle of the first portion of the base plate and the second portion of the base plate is too large, the oblique angle of the airflow is too large, and the components on the PCB below will be blown towards the side. Therefore, the oblique angle of the airflow cannot be too large.

According to the first aspect described above, the base plate includes an integral flat plate, the first portion and the second portion of the base plate are formed by bending the integral flat plate, and the first through holes on the first portion of the base plate and the second through holes on the second portion of the base plate are formed by stamping.

According to the first aspect described above, the axial direction of the through holes is perpendicular to the plane in which the flat plate is located.

According to the first aspect described above, the axial direction of the plurality of through holes of the base plate is perpendicular to the horizontal direction of the furnace chamber. At this time, the airflow flowing vertically downward from the top of the furnace chamber flows smoothly in a direction parallel to the axial direction of the through holes, so as not to blow the components on the PCB below.

According to the first aspect described above, the base plate includes a body and a side edge, the side edge including a rounded corner connected with the body, the rounded corner configured to be angled with the horizontal direction of the furnace chamber and inclined to at least one side of the processing area of the cooling zone.

According to the first aspect described above, the plurality of through holes are arranged in rows, and adjacent two rows of through holes form a channel region of fluid flow, the channel region extending to a lower edge of the base plate. The channel region is used to enable the smooth flow of the flux downward.

According to the first aspect described above, the cooling zone includes: a collection tank positioned below the base plate to collect fluid flowing out along the bottom surface of the base plate.

A second aspect of the present application provides a cooling zone including the furnace chamber described above.

The concepts, specific structures, and technical effects of the present application will be further explained below in conjunction with the appended drawings to fully understand the purpose, features, and effects of the present application.

### BRIEF DESCRIPTION OF DRAWINGS

FIG. 1A shows a schematic perspective view of a portion of a furnace chamber 100 according to one example of the present application;

FIG. 1B is a top view of the furnace chamber 100 of FIG. 1A;

FIG. 1C is a cross-sectional view of the furnace chamber 100 of FIG. 1B along section line A-A;

FIG. 1D is a partial enlarged view of the furnace chamber 100 of FIG. 1C;

FIG. 1E is a front view of the furnace chamber 100 of FIG. 1A;

FIG. 1F is a cross-sectional view of the furnace chamber 100 of FIG. 1E along section line B-B;

FIG. 2A shows a perspective view of an upper cooling box 110 of a first cooling zone 14 in FIG. 1B;

FIG. 2B is a front view of the upper cooling box 110 of FIG. 2A;

FIG. 2C is a top view of the upper cooling box 110 of FIG. 2A;

FIG. 2D is a bottom view of the upper cooling box 110 of FIG. 2A;

FIG. 2E is a perspective view of the upper cooling box 110 in FIG. 2A with its housing removed;

FIG. 2F is a top view of the upper cooling box 110 in FIG. 2E, and FIG. 2G is a cross-sectional view of the upper cooling box 110 in FIG. 2C along section line B-B;

FIG. 2H is a cross-sectional view of the upper cooling box 110 in FIG. 2B along section line A-A;

FIG. 3A shows a perspective view of a base plate 200 of FIG. 2A;

FIG. 3B is a front view of the base plate 200 of FIG. 3A;

FIG. 3C is a bottom view of the base plate 200 of FIG. 3A;

FIG. 3D is a partially enlarged view of the base plate 200 of FIG. 3A;

FIG. 4A shows a cross-sectional schematic view of a first example of the base plate 200 of FIG. 3A;

FIG. 4B shows a cross-sectional schematic view of a second example of the base plate 200 of FIG. 3A;

FIG. 4C shows a cross-sectional schematic view of a third example of the base plate 200 of FIG. 3A;

FIG. 4D shows a cross-sectional schematic view of a fourth example of the base plate 200 of FIG. 3A;

FIG. 4E shows a cross-sectional schematic view of a fifth example of the base plate 200 of the present application;

FIG. 4F shows a cross-sectional schematic view of a sixth example of the base plate 200 of the present application; and

FIG. 5 shows a simplified structural schematic view of one example of a filter device 501 of the present application.

### DETAILED DESCRIPTION

Various specific embodiments of the present application will be described below with reference to the attached drawings that form a part of the present specification. It should be understood that while terms denoting orientation, such as “front”, “rear”, “upper”, “lower”, “left”, “right”, “top”, “bottom”, “side”, etc., are used in the present application to describe various exemplary structural parts and elements of the present application, these terms are used herein for convenience of illustration only and are determined based on the exemplary orientations shown in the appended drawings. Since the examples disclosed in the present application may be disposed in different orientations, these terms denoting orientation are for illustrative purposes only and should not be considered as limiting.

Those skilled in the art shall understand that the exhaust gas, gas, or airflow described in this example refers to an ingredient that is mostly gaseous, which may also comprise a portion of a liquid or solid ingredient.

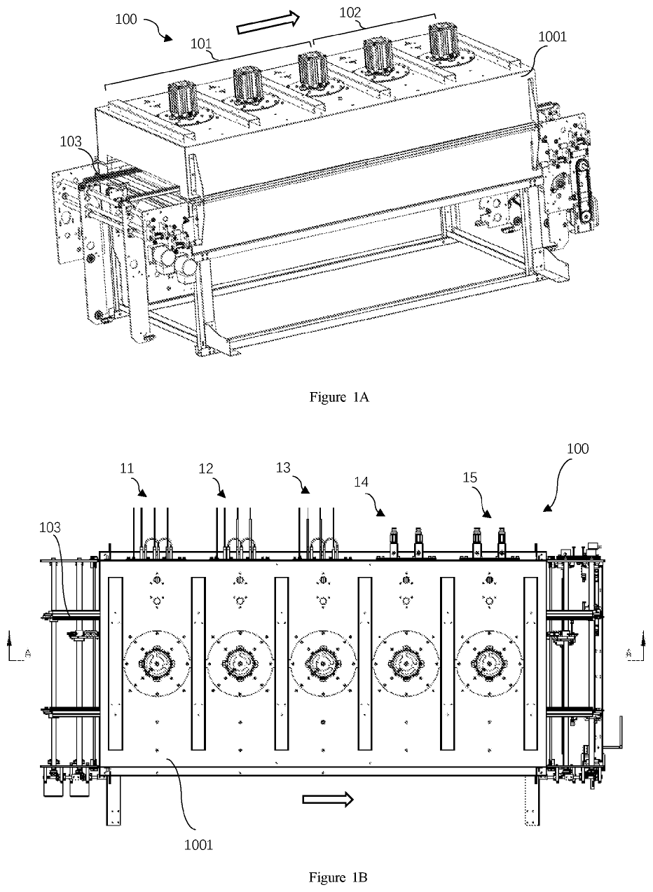

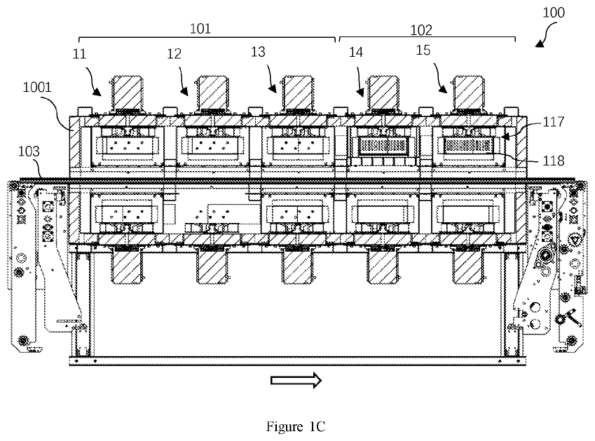

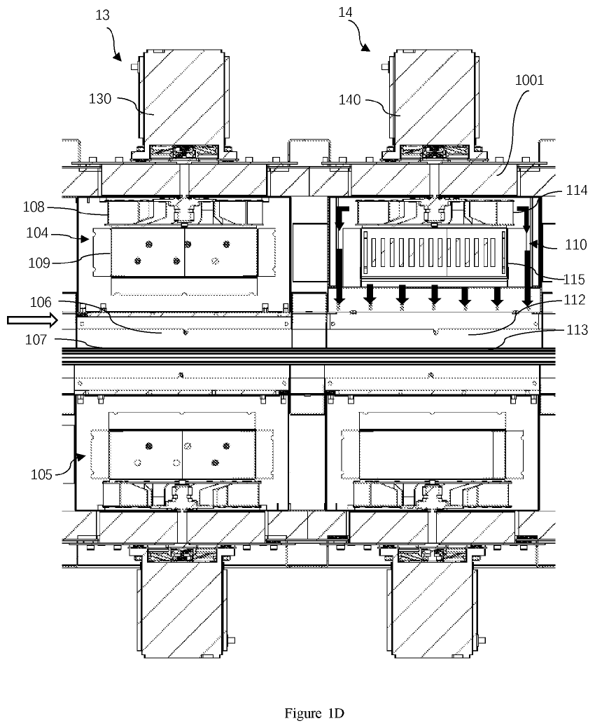

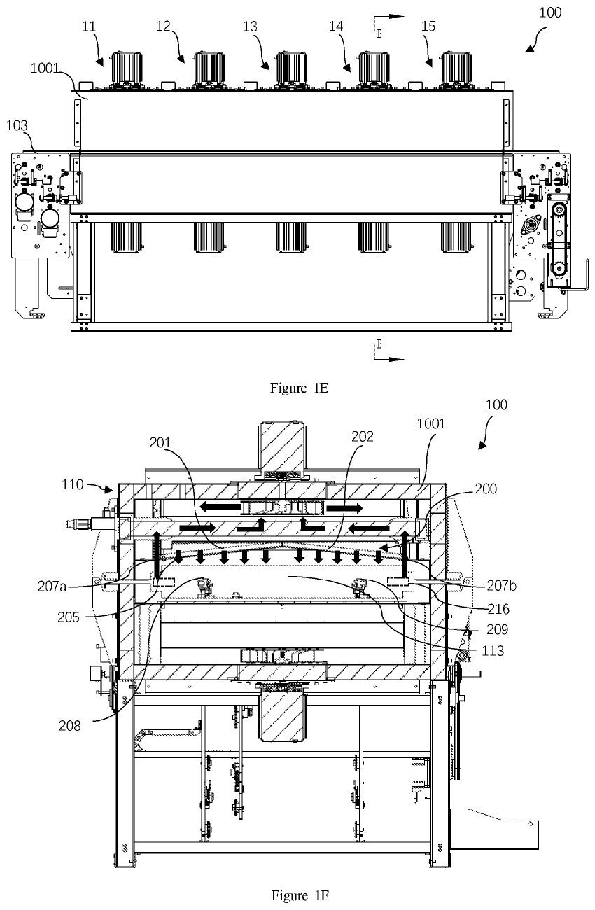

FIG. 1A shows a schematic perspective view of a portion of the furnace chamber 100 according to an example of the present application. FIG. 1B is a top view of FIG. 1A. FIG. 1C is a cross-sectional view of FIG. 1B along section line A-A. FIG. 1D is an enlarged view of a high temperature zone 13 and a cooling zone 14 of FIG. 1C. FIG. 1E is a front view of FIG. 1A, and FIG. 1F is a cross-sectional view of FIG. 1E along section line B-B. In one example, the furnace chamber 100 is used for a reflow furnace. In other examples, the furnace chamber 100 may be used for other suitable devices or apparatuses.

FIGS. 1A to C illustrate a portion of the furnace chamber 100, i.e., a high temperature zone 101 and a cooling zone 102 in the furnace chamber 100.

Upstream of the high temperature zone 101, the furnace chamber 100 also includes a preheating zone and a homogenizing zone (not shown). The furnace chamber 100 also includes a conveying apparatus that conveys a circuit board sequentially through the preheating zone, the homogenizing zone, the high temperature zone 101, and the cooling zone 102 so that the circuit board is preheated, refluxed, and cooled after reflux. The conveying apparatus includes a conveying device 103 located in the high temperature zone 101 and the cooling zone 102. The circuit board includes a deposited solder paste and electronic components. In the preheating zone and the homogenizing zone, the circuit board is preheated in preparation for reflux. In the high temperature zone 101, the temperature rapidly rises to a reflux temperature in order to reflux the solder paste deposited on the circuit board. Next, in the cooling zone 102, the temperature drops below the reflux temperature to cool the circuit board to electrically and mechanically connect the wires of the electronic components to the circuit board. As shown in FIGS. 1A to F, the furnace chamber 100 includes an outer housing 1001 for enclosing a heating box of the high temperature zone 101 and a cooling box of the cooling zone 102. The outer housing 1001 includes a top, a bottom, a left, a right, a front, and a rear.

As shown in FIGS. 1B to C, the high temperature zone 101 includes a first high temperature zone 11, a second high temperature zone 12, and a third high temperature zone 13, and the cooling zone 102 includes a first cooling zone 14 and a second cooling zone 15. The conveying device 103 sequentially conveys the circuit board from left to right to the first high temperature zone 11, the second high temperature zone 12, and the third high temperature zone 13 for heating reflux, and then from left to right to the first cooling zone 14 and the second cooling zone 15 for cooling (as shown by the arrows in FIGS. 1B to C). In other examples, the furnace chamber 100 includes any suitable number of high temperature zones and cooling zones required. The circuit board is provided on the conveying device 103 and is conveyed sequentially by the conveying device 103 through the high temperature zone 101 and the cooling zone 102. When the high temperature zone 101 and the cooling zone 102 are processing accordingly, the areas on the conveying device 103 of the circuit board are referred to as processing areas, such as processing areas 107 and 113 illustrated in FIG. 1D. In one example, the processing area includes a rectangular area that includes two sides along the conveying direction of the circuit board (e.g., two sides 208, 209 of the processing area 113 shown in FIG. 1F), and the circuit board is conveyed along the two sides through the high temperature zone and the cooling zone without sacrificing the two sides. In other examples, the processing area includes any other suitable shaped areas.

As shown in FIG. 1D, the third high temperature zone 13 is adjacent and in communication with the first cooling zone 14. The third high temperature zone 13 includes an upper heating box 104, a lower heating box 105, and a heating chamber 106 located between the upper heating box 104 and the lower heating box 105, the heating chamber 106 including a processing area 107 where the circuit board is heated. The upper heating box 104 is used to transfer hot air flow from above to the circuit board in the processing area 107 and the lower heating box 105 is used to transfer hot air flow from below to the circuit board in the processing area 107. In other examples, it is possible to use the upper heating box only to heat the circuit board. The upper heating box 104 includes a blower 108 and a heater 109 arranged sequentially from top to bottom. In operation, the blower 108 draws airflow from the heating chamber 106 upwards to the heater 109, generates a hot airflow after passing the heater 109. Then the hot airflow passes through the blower 108 and flows from the blower 108 downwards the bottom of the upper heating box 104 and out of the bottom to the heating chamber 106 below, thereby heating the circuit board in the heating chamber 106. The flow of the airflow in the high temperature zone is similar to that of the airflow in the cooling zone (see below for details). The blower 108 is electrically connected with a motor 130 disposed above for driving the blower 108 to operate. The structure of the lower heating box 105 is the same or substantially the same as the structure of the upper heating box 104.

As shown in FIG. 1D, the first cooling zone 14 includes an upper cooling box 110 and a cooling chamber 112 located below the upper cooling box 110, the cooling chamber 112 including a processing area 113 where the circuit board is cooled. The upper cooling box 110 is used to deliver cold airflow from above to the circuit board in the processing area 113. The upper cooling box 110 includes a blower 114 and a heat exchange device 115 disposed sequentially from top to bottom. As shown in FIG. 1F, in operation, the blower 114 draws airflow in the cooling chamber 112 from both ends of the bottom of the upper cooling box 110 (near the front and rear of the outer housing 1001 of the furnace chamber 100) up along the front and rear sides within the upper cooling box 110 to the heat exchange device 115, the airflow passing through the heat exchange device 115 being cooled to produce a cool airflow that flows into the blower 114 after passing through the heat exchange device 115 (as shown by the arrows in FIG. 1F). Then, as shown in FIG. 1D, after passing through the blower 114, the cool airflow flows downwardly from the left and right sides within the upper cooling box 110 to the base plate 200 and then out from the base plate 200 into the cooling chamber 112 below (as shown by the arrows in FIG. 1D), thereby cooling the circuit board in the cooling chamber 112. The blower 114 is electrically connected with a motor 140 disposed above the blower for driving the blower 114 to operate. In other examples, a lower cooling box may be provided to transfer cold airflow from below to the circuit board in the processing area 113 to cool the circuit board. The structure of the lower cooling box includes existing cooling box structures. For example, the base plate of the lower cooling box is flat and disposed parallel to the horizontal direction of the furnace chamber 100.

The heating chamber 106 of the third high temperature zone 13 is in communication with the cooling chamber 112 of the first cooling zone 14, so that the processing area 107 of the heating chamber 106 is in communication with the processing area 113 of the cooling chamber 112. In operation, the conveying device 103 conveys the circuit board to the processing area 107 in the heating chamber 106 for heating and then to the processing area 113 of the cooling chamber 112 for cooling.

As shown in FIGS. 1A to C, the structure of the first high temperature zone 11 and the second high temperature zone 12 is the same or substantially the same as the structure of the third high temperature zone 13. In other examples, the structure of the first high temperature zone 11 and the second high temperature zone 12 may be different from the structure of the third high temperature zone 13. The structure of the second cooling zone 15 is different from the structure of the first cooling zone 14, such as the upper cooling box 117 of the second cooling zone 15 being different from the upper cooling box 110 of the first cooling zone 14, while the other structures of the second cooling zone 15 are the same as the other structures of the first cooling zone 14. As shown in FIGS. 1C to D and 1F, the base plate 118 of the upper cooling box 117 of the second cooling zone 15 is a flat plate and disposed parallel to the horizontal direction of the furnace chamber 100, while the base plate 200 of the upper cooling box 110 of the first cooling zone 14 is divided into a first portion 201 and a second portion 202, the first portion 201 and the second portion 202 extending obliquely from both sides of the symmetrical axis at an angle at their joining point (or bending point), forming two symmetrical base plate portions arranged obliquely. The first portion 201 and the second portion 202 are respectively inclined to two sides 208, 209 of the processing area 113 in the conveying direction of circuit boards. In other examples, the structure of the second cooling zone 15 is the same as the structure of the first cooling zone 14.

In the high temperature zone 101, VOCs (volatile organics) in the flux vaporize to form vapors, thereby forming “contaminants” that mix with the working gas in the high temperature zone to form exhaust gases. As the exhaust gas flows from the high temperature zone 101 to the cooling zone 102 and is cooled, the flux in the exhaust gas condenses to the bottom surface of the base plate of the upper cooling box 110. In the prior art, the base plate is set parallel to the horizontal direction of the furnace chamber, so that the flux condensed on the bottom surface of the base plate can drip onto the circuit board below the bottom surface due to continuous accumulation and cold air flow flowing down from the base plate, thereby damaging the circuit board.

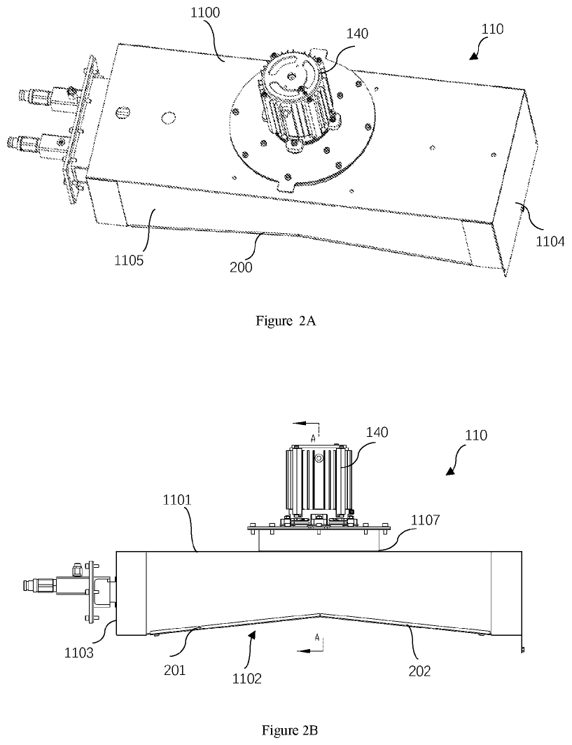

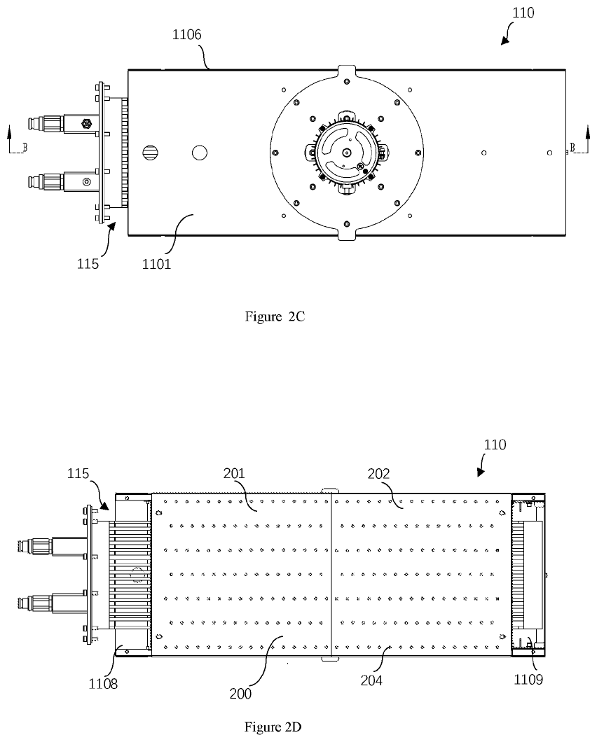

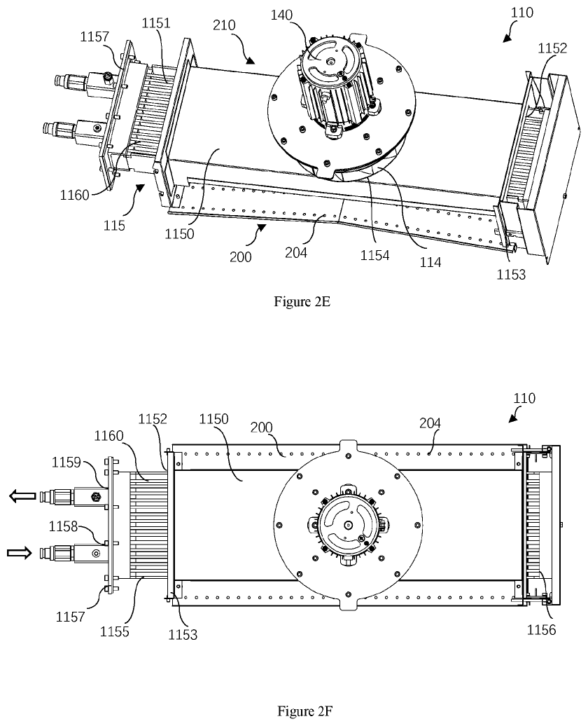

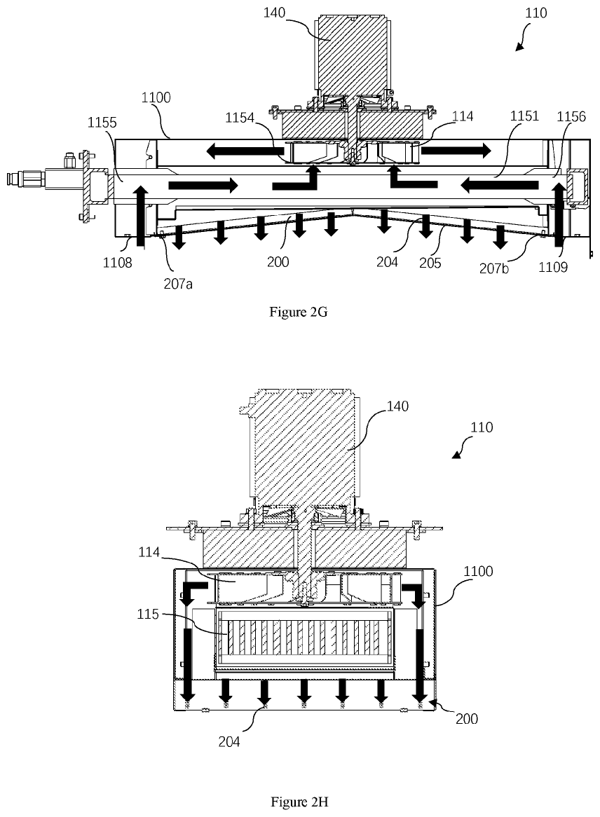

To overcome the above problems, the present application sets at least a portion of the bottom surface 205 of the base plate 200 of the upper cooling box 110 in the first cooling zone 14 at an angle to the horizontal direction of the furnace chamber 100 and inclined to at least one side of the processing area 113 of the cooling chamber 112 in the conveying direction of circuit boards (see FIGS. 1F, 2A to H, 3A to C, and 4A to F). The base plate 200 includes a lower edge to which the flux condensed on the bottom surface 205 of the base plate 200 flows along a ramp of the bottom surface 205. The base plate 200 is located above the processing area 113, with the lower edge of the base plate 200 located in an area outside of the at least one side of the processing area 113, as viewed from above. In this way, the flux condensed on the bottom surface 205 of the base plate 200 flows along the ramp to at least one side of the cooling furnace chamber along the conveying direction of circuit boards, out of the lower edge of the base plate 200 and drips to an area outside of at least one side of the processing area 113 without dripping onto the circuit board in the processing area 113. Also, as the flux flows out from the lower edge of the base plate 200 to drip to an area outside of at least one side of the processing area 113 along the conveying direction of the circuit board, even when the circuit board is passing through the processing area 113 along the conveying direction, the flux condensed on the bottom surface 205 of the base plate 200 does not drip onto the circuit board beneath. This is because the flux drips to the area outside the processing area 113 beneath along the conveying direction of the circuit board.

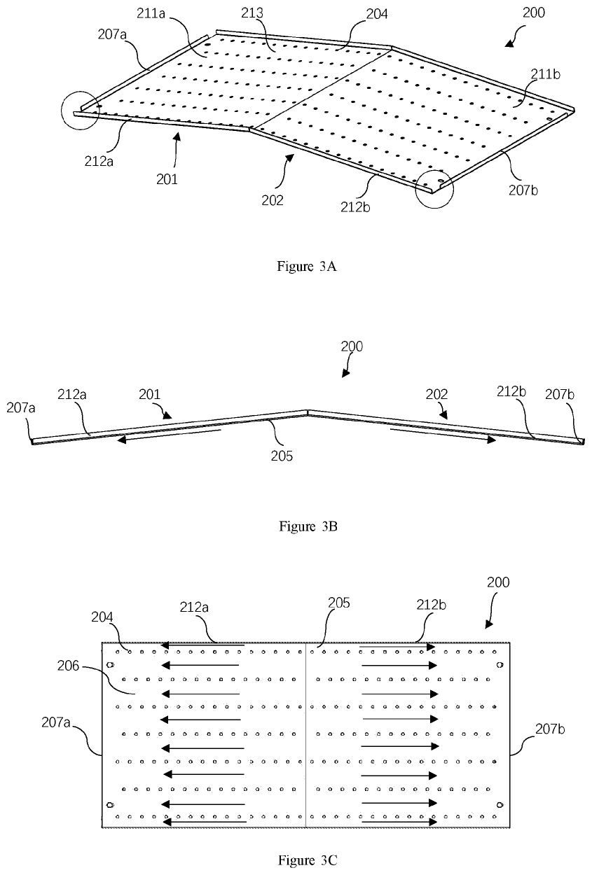

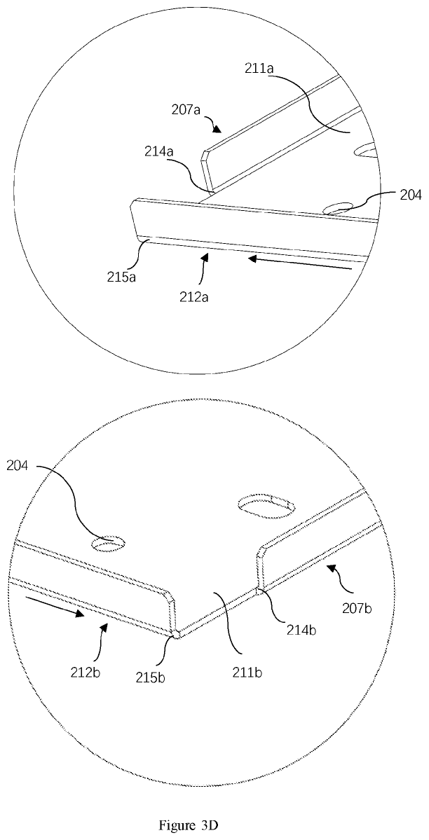

In one example, as shown in FIG. 1F, the base plate 200 is divided into a first portion 201 and a second portion 202 that are symmetrically arranged, the first portion 201 and the second portion 202 extending obliquely from both sides of the symmetrical axis at an angle at their joining point (or bending point), forming two symmetrical base plate portions obliquely disposed. The first and second portions 201, 202 are respectively inclined to two sides 208, 209 of the processing area 113 in the conveying direction of the circuit board. The base plate 200 includes a bent flat plate, for example formed by a bent flat plate. In other examples, the base plate is formed in other suitable ways. The base plate 200 includes lower edges 207a, 207b (see FIGS. 3A to D), and the flux condensed on the bottom surface 205 of the base plate 200 flows along a ramp of the bottom surface 205 to the lower edges 207a, 207b. The base plate 200 is located above the processing area 113, with the lower edges 207a, 207b of the base plate 200 located in an area outside of the two sides 208, 209 of the processing area 113, as viewed from above. In this way, the flux condensed on the bottom surface 205 of the base plate 200 flows along the ramp to both sides of the cooling furnace chamber in the conveying direction of circuit boards, out of the lower edges 207a, 207b of the base plate 200 and drips to areas outside of both sides 208, 209 of the processing area 113 without dripping onto the circuit board in the processing area 113. Also, as the flux flows out of the lower edges 207a, 207b of the base plate 200 and drips to areas outside of the two sides 208, 209 of the processing area 113 along the conveying direction of the circuit board, the flux condensed on the bottom surface 205 of the base plate 200 does not drip onto the circuit board beneath it even when the circuit board is passing through the processing area 113 along the conveying direction. This is because the flux drips to the areas outside of the processing area 113 below along the conveying direction of the circuit board. Below the base plate 200, such as below the lower edges 207a, 207b of the base plate 200, a collection tank 216 (shown as a dashed line) may be provided for collecting the flux dripping from the lower edges 207a, 207b of the base plate 200. The collection tank may be an additionally provided collection tank or a collection device originally in the furnace chamber.

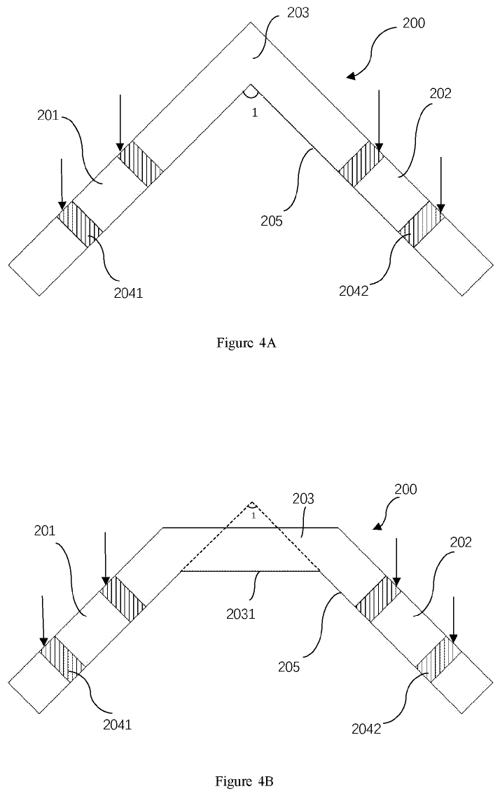

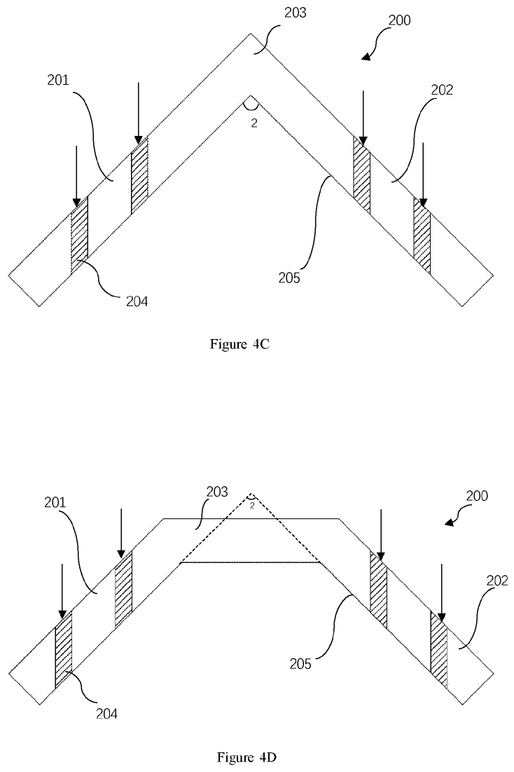

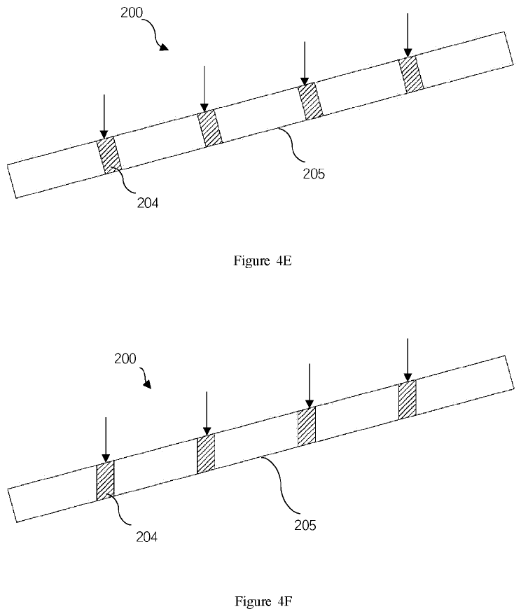

In another example, the bottom surface 205 of the base plate 200 of the upper cooling box 110 is provided to be inclined to one side of the processing area 113 of the cooling chamber 112 (see FIGS. 4E to F). The base plate includes a flat plate. In other examples, the upper cooling box 117 of the second cooling zone 15 may be disposed the same as the upper cooling box 110 of the first cooling zone 14. The present application extends the maintenance time, for example by 1 month or 1 half month, of the cooling zone by improving the base plate of the upper cooling box of the cooling zone.

FIG. 2A shows a perspective view of the upper cooling box 110 of the first cooling zone 14 of FIG. 1B. FIG. 2B is a front view of FIG. 2A. FIG. 2C is a top view of FIG. 2A. FIG. 2D is a bottom view of FIG. 2A. FIG. 2E is a perspective view of FIG. 2A with the housing removed (only the bottom of the housing is remained). FIG. 2F is a top view of FIG. 2E. FIG. 2G is a cross-sectional view of FIG. 2C along the section line B-B, and FIG. 2H is a cross-sectional view of FIG. 2B along the section line A-A.

As shown in FIGS. 2A to D, the upper cooling box 110 includes a box-like outer housing 1100 that includes a top 1101, a bottom 1102, a left 1103, a right 1104, a front 1105, and a rear 1106. The top 1101 of the outer housing 1100 includes an opening 1107 to enable the motor 140 above the top 1101 to be electrically connected with the blower 114 within the outer housing 1100. The left 1103 of the outer housing 1100 includes an opening through which the heat exchange device 115 can extend to an exterior of the outer housing 1100. The bottom 1102 of the outer housing 1100 includes a base plate 200 having a length that is less than the length of the top 1101 of the outer housing 1100, and openings 1108, 1109 located on both sides of the base plate 200. The openings 1108, 1109 enable the upper cooling box 110 to be in fluid communication with the cooling chamber 112 below at the bottom 1102.

As shown in FIGS. 2E to H, the outer housing 1100 houses an airflow source 210 that is provided above the base plate 200, and a through hole 204 is provided on the base plate 200. The airflow source 210 is used to deliver airflow to the base plate 200 and deliver the airflow through the through holes 204 on the base plate 201 to reach the processing area 113 of the cooling chamber 112 below to process the circuit board. The airflow includes a cold airflow. In other examples, the airflow includes other suitable airflows. The airflow source 210 includes a blower 114 and a heat exchange device 115 arranged sequentially in the outer housing 1100 from top to bottom. In the outer housing 1100, the blower 114 is disposed proximate the top 1101 of the outer housing 1100 and is electrically connected with the motor 140 above the top 1101, and the motor 140 is used to drive the blower 114 to work. The heat exchange device 115 is disposed below the blower 114.

The heat exchange device 115 includes a housing 1150 and a heat exchanger 1151 partially located in the housing. The housing 1150 includes a top, a bottom, a left, a right, a front, and a rear. Both the left and right portions of the housing 1150 include an opening 1152 formed by a combination of the top, the bottom, the front, and the rear portions of the housing 1150, and a flange 1153 that extends around the opening 1152 and towards the outer side of the opening 1152. The flange 1153, the housing 1150, and the base plate 200 form a box structure. The top of the housing 1150 includes an opening 1154. The heat exchange device 115 is in fluid communication with the blower 114 through the opening 1154 at the top. The bottom of the housing 1150 is disposed above the base plate 200 and spaced a distance from the base plate 200, and the base plate 200 is in fluid communication with the blower 114. The heat exchanger 1151 includes a left end 1155 and a right end 1156 extending from the openings 1152 of the left and right portions of the housing 1150 to the exterior of the housing 1150, respectively. The left end 1155 of the heat exchanger 1151 is fixed to a plate 1157, which is secured to the outer housing 1001 (see FIG. 2A). The plate 1157 includes an inlet 1158 and an outlet 1159 to receive and discharge a cooling medium, respectively (as shown by the arrows in FIG. 2F).

The heat exchanger 1151 includes a plurality of cooling plates 1160 disposed side-by-side, and the interior of each cooling plate 1160 may contain a cooling medium with a desired cooling airflow flowing outside the cooling plate 1160. The cooling medium inside the cooling plate 1160 exchanges heat with the airflow outside the cooling plate 1160 through the outer peripheral side walls of the cooling plate 1160, reducing the temperature of the airflow so that the heat exchanger 1151 outputs the cold airflow. The interior of these cooling plates 1160 is in fluid communication to form a cooling medium channel through which a cooling medium may flow. The cooling medium channel includes an inlet and an outlet of the cooling medium channel in fluid communication with the inlet 1155 and the outlet 1156, respectively. In operation, the cooling medium enters the inlet of the cooling medium channel from the inlet 1158, flows through the cooling medium channel, flows out of the outlet of the cooling medium channel, and flows out of the upper cooling box 110 from the outlet 1159. The blower 114 draws the airflow in the cooling chamber 112 through the openings 1108 and 1109 on both sides of the bottom plate 200 of the bottom 1102 to the left end 1155 and the right end 1156 of the heat exchanger 1151 from bottom to top, respectively. The airflow flows from the left end 1155 and the right end 1156 towards the center of the heat exchanger 1151 outside the cooling plate of the heat exchanger 1151 (as indicated by the arrows in FIG. 2G), at which point the airflow is cooled through the heat exchanger 1151, creating a cool airflow. Then, the cold airflow enters the blower 114 through the opening 1154 at the top, and the blower 114 blows the cold airflow from the top down to the base plate 200 in communication therewith. The cold air flows out through the through hole 204 of the base plate 200 into the cooling chamber 112 (as shown by the arrow in FIG. 2H), thereby cooling the circuit board in the cooling chamber 112.

As the exhaust gas of the high temperature zone 101 flows to the cooling zone 102, the exhaust gas is cooled by heat exchange with the cold airflow in the cooling chamber 112, so that the flux in the exhaust gas condenses to the bottom surface 205 of the base plate 200 of the upper cooling box 110. As shown in FIGS. 1F and 2A to G, the bottom surface 205 faces the lower cooling chamber 112 and the circuit board is disposed in the processing area 113 of the cooling chamber 112 for cooling process. The base plate 200 is divided into a first portion 201 and a second portion 202 disposed symmetrically, the first portion 201 and the second portion 202 extending obliquely from both sides of the symmetrical axis at an angle at their joining point (or bending point), forming two symmetrical base plate portions obliquely disposed. The first and second portions 201, 202 are respectively inclined to two sides 208, 209 of the processing area 113 in the conveying direction of circuit boards. The base plate 200 includes the lower edges 207a, 207b (see FIGS. 3A to D) to which the flux condensed on the bottom surface 205 of the base plate 200 flows along a ramp of the bottom surface 205. The base plate 200 is located above the processing area 113, with the lower edges 207a, 207b of the base plate 200 located in an area outside of the two sides 208, 209 of the processing area 113, as viewed from above. In this way, the flux condensed on the bottom surface 205 of the base plate 200 flows along the ramp to both sides of the cooling furnace chamber in the conveying direction of circuit boards, out of the lower edges 207a, 207b of the base plate 200 and drips to areas outside of both sides 208, 209 of the processing area 113 without dripping onto the circuit board in the processing area 113. Also, as the flux flows out of the lower edges 207a, 207b of the base plate 200 and drips to an area outside of the two sides 208, 209 of the processing area 113 along the conveying direction of the circuit board, the flux condensed on the bottom surface 205 of the base plate 200 does not drip onto the circuit board beneath it even when the circuit board is passing through the processing area 113 along the conveying direction. This is because the flux drips to the area outside the processing area 113 along the conveying direction of the circuit board. In other examples, the base plate 200 includes any other suitable shape and structure.

FIG. 3A shows a perspective view of the base plate 200 of FIG. 2A. FIG. 3B is a front view of FIG. 3A. FIG. 3C is a bottom view of FIG. 3A, and FIG. 3D is a partially enlarged view of FIG. 3A.

As shown in FIGS. 3A to B, the base plate 200 includes a top surface 213 facing the heat exchange device 115 and a bottom surface 205 facing the processing area 113 (see FIG. 1F). As shown in FIGS. 3A to D, the base plate 200 includes a first portion 201 and a second portion 202 disposed symmetrically along an axis of symmetry, the first portion 201 and the second portion 202 extending obliquely downward at their joining point at an angle from both sides of the symmetrical axis, forming two symmetrical base plate portions arranged obliquely. As shown in FIGS. 3A to D, the first portion 201 of the base plate 200 includes a body 211a, a lower edge 207a, and a side edge 212a. The left portion of the body 211a is connected to the lower edge 207a, and the front and rear portions of the body 211a are connected to the side edge 212a. The body 211a includes a flat plate. The lower edge 207a is provided as a long narrow plate with a rounded corner 214a that is connected with the body 211a, and the long narrow plate extends upwardly away from the bottom surface 205. Similarly, the side edge 212a is provided as a long narrow plate with a rounded corner 215a that is connected with the body 211a, and the long narrow plate extends upwardly away from the bottom surface 205. The lower edge 207a extends along a partial length of the left portion of the body 211a and the side edge 212a extends along the entire length of the front and rear portions of the body 211a. The body 211a is integrally formed with the lower edge 207a and the side edge 212a. In other examples, the body 211a is connected with the lower edge 207a and the side edge 212a in other suitable ways. The second portion 202 is provided as a mirror image with respect to the first portion 201, the second portion 202 including a body 211b, a lower edge 207b, and a side edge 212b, the lower edge 207b being provided as a long narrow plate with a rounded corner 214b, and the side edge 212b being provided as a long narrow plate with a rounded corner 215b.

As shown in FIGS. 3A and 3C, a plurality of through holes 204 are provided on the bodies 211a and 211b, and the plurality of through holes 204 are arranged in rows. On the bottom surface 205 of the base plate 200, adjacent two rows of through holes 204 form a channel region 206 of fluid flow, and the channel region 206 extends to the lower edges 207a, 207b of the base plate 200. In this way, the flux condensed onto the bottom surface 205 of the base plate 200 can flow along the channel region 206 on the bottom surface 205 to the lower edges 207a, 207b (as indicated by the arrows) and drip down from the lower edges 207a, 207b to areas outside the two sides 208, 209 of the processing area 113 (see FIG. 1F) without dripping onto the circuit board at the processing area 113. Since the cold air flows downward through the through hole 204, the flux does not flow into the through hole 204. In a row of through holes 204, the flux between adjacent two through holes 204 flows around the through hole 204 to the channel region 206 and along the channel region 206 to the lower edges 207a, 207b. As the flux flows to the lower edge 207a, 207b, the flux accumulates at the rounded corners 214a, 214b of the lower edge 207a, 207b and then drips down to an area outside the processing area 113 below without dripping onto the circuit board in the processing area 113. As shown in FIG. 3C, a channel region 206 is also formed between a row of through holes 204 proximate the side edge 212a and the side edge 212a, and the flux flows down to the edge 207a along the channel region 206. A channel region 206 is also formed between a row of through holes 204 proximate the side edge 212b and the side edge 212b, and the flux flows down to the edge 207b along the channel region 206. When the flux flows towards the side edges 212a, 212b, the flux flows to the rounded corners 215a, 215b of the side edges 212a, 212b. The flux at the rounded corners 215a, 215b does not drip directly vertically down to cause dripping onto the circuit board, for example, to cause dripping onto the circuit board as the circuit board passes through the processing area 113. Because the side edges 212a, 212b are inclined downwardly from the axis of symmetry to both sides (e.g., the lower edges 207a, 207b), as shown in FIGS. 3B to D, the flux at the rounded corners 215a, 212b of the side edges 212a, 212b flows downwardly along the ramp of the rounded corner 215 (towards the lower edges 207a, 207b) (as shown by the arrows in FIGS. 3B and 3D), out from the ends of the rounded corners 215a, 215b (near the lower edges 207a, 207b) and drips to an area outside the processing area 113 below.

FIG. 4A shows a cross-sectional schematic view of a first example of the base plate 200 in FIG. 3A. FIG. 4B shows a cross-sectional schematic view of a second example of the base plate 200 in FIG. 3A. FIG. 4C shows a cross-sectional schematic view of a third example of the base plate 200 in FIG. 3A. FIG. 4D shows a cross-sectional schematic view of a fourth example of the base plate 200 in FIG. 3A. FIG. 4E shows a cross-sectional schematic view of a fifth example of the base plate 200 in the present application, and FIG. 4F shows a cross-sectional schematic view of a sixth example of the base plate 200 in the present application.

As shown in FIGS. 4A to D, the base plate 200 includes a first portion 201, a second portion 202, and an adapter 203, the first portion 201 and the second portion 202 being bent in connection at the adapter 203, and the first portion 201 and the second portion 202 extending obliquely downward from the adapter 203 to the two sides 208, 209 of the processing area 113 along the conveying direction of the circuit board at an angle with the horizontal direction of the furnace chamber 100. As shown in FIGS. 4A and 4B, the base plate 200 includes a bottom surface 205, and when the exhaust gases are cooled in the cooling zone, the flux in the exhaust gases condenses on the bottom surface 205 of the base plate 200. A plurality of first through holes 2041 are provided on the first portion 201 (for example, the body 211a) of the base plate 200, and a plurality of second through holes 2042 are provided on the second portion 202 (for example, the body 211b) of the base plate 200. The axial direction of the first through holes 2041 is perpendicular to the plane where the first portion 201 of the base plate is located, and the axial direction of the second through holes 2042 is perpendicular to the plane where the second portion 202 of the base plate is located. In one example, the first through holes 2041 and the second through holes 2042 are formed by stamping. In other examples, the first through hole 2041 and the second through hole 2042 are formed in other suitable ways, such as laser perforations. As shown in FIG. 4A, the adapter 203 between the first portion 201 of the base plate and the second portion 202 of the base plate is pointed. In one example, the adapter 203 is formed from connection of adjacent edges of the first portion 201 of the base plate and the second portion 202 of the base plate, and the connection includes any suitable ways of connection, such as welding. In one example, the base plate 200 includes an integral flat plate from which the first portion 201 of the base plate and the second portion 202 of the base plate are bent and formed.

As compared to FIG. 4A, as shown in FIG. 4B, the adapter 203 between the first portion 201 of the base plate and the second portion 202 of the base plate includes a flat portion, for example, the bottom surface 2031 of the adapter 203 being flat. FIG. 4B is merely a structural schematic view of the base plate 200. In an actual structure, the bottom surface 2031 of the adapter 203 of the base plate 200 is narrow and has a small area, so that the amount of flux condensed thereon is relatively small without substantially affecting the maintenance time of the cooling zone. The structure of the base plate of FIG. 4B may still achieve approximately the same effect as the effect achieved by the base plate in FIG. 4A. In one example, the adapter 203 includes a long narrow flat plate. The adapter 203 connects adjacent edges of the first portion 201 of the base plate and the second portion 202 of the base plate at two long edges thereof, respectively, and the connection includes any suitable means of connection, such as welding. In another example, the base plate 200 includes an integral flat plate from which the first portion 201 of the base plate, the second portion 202 of the base plate, and the adapter 203 are bent and formed. In other examples, the adapter 203 may be inclined, i.e., disposed at an angle relative to the horizontal direction of the furnace chamber. In other examples, the adapter 203 includes other suitable structures.

As shown in FIGS. 4A and 4B, the airflow generated by the airflow source 210 (e.g., a cold airflow) is blown generally vertically downward to the base plate 200 (as indicated by the arrows). As mentioned before, the axial direction of the first through holes 2041 is perpendicular to the plane where the first portion 201 of the base plate is located, and the axial direction of the second through holes 2042 is perpendicular to the plane where the second portion 202 of the base plate is located. Therefore, the airflow that is substantially perpendicular downwards will generate an inclined airflow after passing through the through holes 2041 and 2042. In the first aspect, the bending angle (i.e., the angle of the bending angle ∠1) between the first portion 201 and the second portion 202 may be small to enable the flux condensed onto the bottom surface 205 of the base plate 200 to flow rapidly downward along the ramp of the bottom surface 205, thereby reducing the risk of flux dripping onto the circuit board below. However, in the second aspect, when the bending angle between the first portion 201 and the second portion 202 is small, the inclination angle of the airflow flowing out of the through holes 2041, 2042 is large, and thus the electronic components on the circuit board below the base plate 200 will be blown towards the side. Therefore, the bending angle between the first portion 201 and the second portion 202 cannot be too small. Thus, the bending angle between the first portion 201 of the base plate and the second portion 202 of the base plate needs to be set in a suitable range such that the risk of flux condensed to the base plate 200 dripping onto the circuit board below can be reduced without blowing the electronics on the circuit board below the base plate 200 towards the side. In addition, from the perspective of the occupied space, when the bending angle between the first portion 201 of the base plate and the second portion 202 of the base plate is relatively small, the base plate 200 takes up a larger amount of space, thereby making the space less utilized. Moreover, if the structure of the original cooling box does not meet the needs of the space used after the base plate is improved, a large modification of the structure of the original cooling box needs to be made, and other structures of the cooling zone and/or the high temperature zone may also need to be improved, resulting in the cost of improvement being too high. In the case that the available space of the original cooling box structure is certain, in order to minimize the improvement of the original cooling box structure, the present application sets the bending angle between the first portion 201 of the base plate and the second portion 202 of the base plate to a suitable angle such that the base plate 200 does not exceed the available space of the original cooling box structure, thereby reducing the improvement cost. Based on the considerations of the above several aspects, in one example of the present application, the range of the bending angle between the first portion 201 and the second portion 202 is set to 165° to 171°. In another example, the bending angle between the first portion 201 and the second portion 202 is set to 168°.

The structures of the base plate 200 in FIGS. 4C and 4D are the same as the structures of the base plate 200 in FIGS. 4A and 4B, respectively. The difference is that as compared to FIGS. 4A and 4B, as shown in FIGS. 4C and 4D, a plurality of through holes 204 are provided on the first portion 201 and the second portion 202 of the base plate 200, and the axial direction of the through holes 204 is perpendicular to the horizontal direction of the furnace chamber 100. The airflow generally vertically downwards blows to the base plate 200 (as indicated by the arrows) and generally flows downward from the through holes 204 of the base plate 200, so as not to blow the electronics on the circuit board below the base plate 200. Thus, in the examples shown in FIGS. 4C and 4D, the bending angle (i.e., the angle of the bending angle ∠2) between the first portion 201 and the second portion 202 may be set to be small so that the flux condensed onto the bottom surface 205 of the base plate 200 can flow rapidly down the ramp of the bottom surface 205, thereby reducing the risk of flux dripping onto the circuit board below and extending the maintenance time of the cooling zone. However, similar to the above description of FIGS. 4A and 4B, in the case that the available space of the original cooling box structure is certain, in order to minimize improvements to the original cooling box structure and/or other structure, the present application sets the bending angle between the first portion 201 of the base plate and the second portion 202 of the base plate to be as small as possible so that the base plate 200 does not exceed the available space of the original cooling box structure. Based on the considerations of the above several aspects, in one example of the present application, the bending angle between the first portion 201 and the second portion 202 ranges from 165° to 171°. In another example, the bending angle between the first portion 201 and the second portion 202 is 168°.

As shown in FIGS. 4E and 4F, the base plate 200 is disposed at an angle to the horizontal direction of the furnace chamber, and the base plate 200 includes a flat plate. Similar to the base plate 200 in FIG. 3A, a long narrow flat plate provided with rounded corners is included at the peripheral edges of the base plate 200 of FIGS. 4E and 4F. For example, the base plate 200 of FIGS. 4E and 4F includes a structure in which the first portion 201 and the second portion 202 of the base plate 200 of FIG. 3A are modified to be parallel to the horizontal direction of the furnace chamber.

As shown in FIGS. 4E and 4F, a plurality of through holes 204 are provided on the base plate 200, and the base plate 200 includes a bottom surface 205. As the exhaust gas is cooled in the cooling zone, the flux in the exhaust gas condenses to the bottom surface 205 of the base plate 200. As shown in FIG. 4E, the axial direction of the through holes 204 of the base plate 200 is set to be perpendicular to the plane where the base plate 200 is located, so that a generally perpendicular downward airflow (as shown by the arrow) will produce an inclined airflow after passing through the through holes 204. In one example, the through holes 204 are formed by stamping. In other examples, the through holes 204 are formed by other suitable means, such as laser perforations. Similar to the base plates of FIGS. 4A and 4B, the angle formed by the base plate 200 in FIG. 4E and the horizontal direction of the furnace chamber 100 should be set in a suitable range such that the risk of the flux on the bottom surface 205 dripping onto the circuit board below can be reduced without blowing the electronics on the circuit board to the side, and that the improvement costs can be reduced.

As shown in FIG. 4F, the axial direction of the through holes 204 of the base plate 200 is set to be perpendicular to the horizontal direction of the furnace chamber 100, so that after passing through the through holes 204, the substantially vertically downward airflow (as shown by the arrow) is still generally perpendicular downward airflow. Thus, the angle of the base plate 200 to the horizontal direction of the furnace chamber 100 may be set to be large so that the flux condensed onto the bottom surface 205 of the base plate 200 can flow rapidly down the ramp of the bottom surface 205, thereby reducing the risk of flux dripping onto the circuit board below and extending the maintenance time of the cooling zone. However, from the perspective of the occupied space, when the base plate 200 is set at a larger angle to the horizontal direction of the furnace chamber 100, the base plate 200 takes up a larger amount of space, thereby making the space less utilized. Moreover, if the structure of the original cooling box does not meet the needs of the space used, a large modification of the structure of the original cooling box needs to be made, and other structures of the cooling zone and/or the high temperature zone may also need to be improved, resulting in the cost of improvement being too high. Therefore, in the case that the available space of the original cooling box structure is certain, in order to minimize improvements to the original cooling box structure, the present application sets the angle of the base plate 200 to the horizontal direction of the furnace chamber 100 as large as possible without exceeding the available space of the original cooling box structure, thereby reducing the improvement cost.

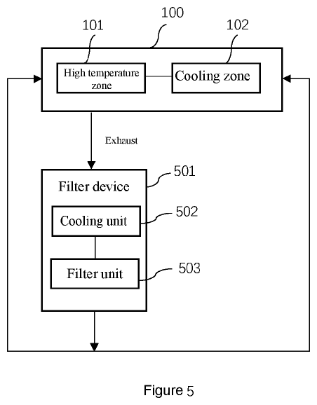

FIG. 5 shows a simplified structural schematic view of one example of a filter device 501 of the present application. As shown in FIG. 5, the filter device 501 is disposed outside the furnace chamber 100 and is in communication with the high temperature zone 101 and the cooling zone 102 of the furnace chamber 100. In operation, the filter device 501 receives exhaust gas from the high temperature zone 101 and filters the exhaust gas to remove contaminants from the exhaust gas. The filtered exhaust gas is condensed as it flows to the cooling zone 102 into a condensate containing relatively more liquid constituents, and the condensate readily flows down the ramp of the base plate, thereby reducing the risk of dripping onto the circuit board below and extending the maintenance time of the cooling zone. When the circuit board is soldered in the furnace chamber using nitrogen as the working gas, the exhaust gas with contaminants filtered out is returned to the high temperature zone 101 and the cooling zone 102. This is because the exhaust gas with contaminants filtered out includes nitrogen and can be used in the soldering operation of the circuit board. Due to the lower content of the flux in the exhaust gas with contaminants filtered out, the contaminants in the high temperature zone 101 and/or the cooling zone 102 are low, and the flux condensed onto the base plate is less, thereby further extending the maintenance time of the high temperature zone 101 and/or the cooling zone 102.

As shown in FIG. 5, the filter device 501 includes a cooling unit 502 and a filter unit 503, the cooling unit 502 and the filter unit 503 being in communication with each other. The cooling unit 502 is used to cool exhaust gases from the high temperature zone 101 to condense the flux in the exhaust gases into solids and/or liquids and collect the solids and/or liquids to cause the cooled exhaust gases to flow out of the cooling unit 502 into the filter unit 503. The filter unit 503 includes a filter mesh for filtering out solids and/or liquids in the cooled exhaust gases described above, thereby outputting the filtered exhaust gases to the high temperature zone 101 and/or the cooling zone 102. In other examples, the filter unit 503 includes a zeolite device and a filter mesh, the zeolite device and the filter mesh being in communication with each other. The zeolite device performs an adsorption operation on the cooled exhaust gas output from the cooling unit 502 to adsorb a portion of the flux in the exhaust gas while discharging the adsorbed exhaust gas. The filter mesh receives adsorbed exhaust gases from the zeolite device and filters out solids and/or liquids in the adsorbed exhaust gases, thereby outputting the filtered exhaust gases to the high temperature zone 101 and/or the cooling zone 102. In other examples, the filter device 501 may include other suitable devices and/or settings for filtering out flux in the exhaust gas.

Although the present disclosure has been described in connection with examples of the examples outlined above, various alternatives, modifications, variations, improvements, and/or substantial equivalents, whether known or foreseeable now or in the near future, may be apparent to those having at least ordinary skill in the art. Therefore, examples of the present disclosure as set forth above are intended to be illustrative and not limiting. Various changes may be made without departing from the spirit or scope of the present disclosure. Therefore, the present disclosure is intended to include all known or earlier developed alternatives, modifications, variations, improvements and/or substantial equivalents. The technical effects and technical problems in this specification are exemplary and not limiting. It should be noted that the examples described in this specification may have other technical effects and may solve other technical problems.

1-15. (canceled)

16. A furnace chamber for a reflow furnace, the furnace chamber comprising a high temperature zone and a cooling zone, wherein the cooling zone includes:
a base plate on which a through hole is provided,
an airflow source provided above the base plate, the airflow source delivering airflow to the base plate and delivering the airflow through the through hole on the base plate,
wherein the base plate includes a bottom surface facing away from the airflow source, at least a portion of the bottom surface being disposed at an angle to a horizontal direction of the furnace chamber;
wherein the cooling zone is provided with a processing area, and the bottom surface being disposed at an angle to the horizontal direction of the furnace chamber is inclined to at least one side of the processing area.

17. The furnace chamber according to claim 16, wherein the bottom surface disposed at an angle to the horizontal direction of the furnace chamber is inclined to both sides of the processing area.

18. The furnace chamber according to claim 16, wherein the base plate includes a bent flat plate.

19. The furnace chamber according to claim 16, wherein the base plate includes a flat plate.

20. The furnace chamber according to claim 16, wherein:
the furnace chamber is used to process a PCB board, the PCB board being placed below the base plate,
the high temperature zone being provided with a processing area, the processing area of the high temperature zone being connected with the processing area of the cooling zone,
during processing, the PCB board is conveyed sequentially through the processing area of the high temperature zone and the processing area of the cooling zone.

21. The furnace chamber according to claim 1, wherein:
the base plate includes a first portion, a second portion, and an adaptor, the first portion and the second portion being bent in connection at the adaptor, and the first portion and the second portion extending downwardly at an angle from the adaptor to both sides of the cooling zone with the horizontal direction of the furnace chamber.

22. The furnace chamber according to claim 21, wherein a plurality of first through holes are provided on the first portion, a plurality of second through holes are provided on the second portion, an axial direction of the first through holes is perpendicular to a plane in which the first portion is located, and an axial direction of the second through holes is perpendicular to a plane in which the second portion is located.

23. The furnace chamber according to claim 21, wherein the bending angle between the first portion and the second portion ranges from 165° to 171°.

24. The furnace chamber according to claim 23, wherein the bending angle between the first portion and the second portion is 168°.

25. The furnace chamber according to claim 21, wherein the base plate includes an integral flat plate, the first portion and the second portion of the base plate being formed by bending the integral flat plate, and the first through holes on the first portion of the base plate and the second through holes on the second portion of the base plate being formed by stamping.

26. The furnace chamber according to claim 25, wherein the axial direction of the through hole is perpendicular to the plane in which the flat plate is located.

27. The furnace chamber according to claim 16, wherein the axial direction of the plurality of through holes of the base plate is perpendicular to the horizontal direction of the furnace chamber.

28. The furnace chamber according to claim 16, wherein the base plate includes a body and a side edge, the side edge including a rounded corner connected to the body, the rounded corner configured to be angled with the horizontal direction of the furnace chamber and inclined to the at least one side of the processing area.

29. The furnace chamber according to claim 16, wherein the plurality of through holes are arranged in rows, and adjacent two rows of through holes form a channel region of fluid flow, the channel region extending to a lower edge of the base plate.

30. The furnace chamber according to claim 29, wherein the cooling zone includes:
a collection tank disposed below the base plate for collecting fluid flowing out along the bottom surface of the base plate.

31. A reflow furnace comprising the cooling zone of the furnace chamber according to claim 16.
